(19) United States
(12) Patent Application Publication
(10) Pub. No.: US 2024/0145488 A1
(43) Pub. Date: May 2, 2024

(54) DISPLAY DEVICE AND DISPLAY SYSTEM

(71) Applicant: Japan Display Inc., Tokyo (JP)

(72) Inventors: Shunichi KIMURA, Tokyo (JP); Mitsutaka OKITA, Tokyo (JP); Toshiharu MATSUSHIMA, Tokyo (JP)

(73) Assignee: Japan Display Inc., Tokyo (JP)

(21) Appl. No.: 18/491,833

(22) Filed: Oct. 23, 2023

(30) Foreign Application Priority Data
Oct. 26, 2022 (JP) 2022-171813

(51) Int. Cl. H01L 27/12

(52) U.S. Cl. CPC H01L 27/124

(57) ABSTRACT

A display device includes an array substrate, and a counter substrate facing the array substrate. The array substrate includes a plurality of signal lines arrayed in a first direction in a manner spaced apart from each other, a plurality of scanning lines arrayed in a second direction in a manner spaced apart from each other, a plurality of pixel electrodes provided to respective openings of pixels each surrounded by two adjacent signal lines and two adjacent scanning lines, a plurality of semiconductors provided to the respective pixels, and a common electrode overlapping the pixel electrodes with an insulating film interposed between the common electrode and the pixel electrodes.

### CROSS-REFERENCE TO RELATED APPLICATION

This application claims the benefit of priority from Japanese Patent Application No. 2022-171813 filed on Oct. 26, 2022, the entire contents of which are incorporated herein by reference.

### BACKGROUND

### 1. Technical Field

The present disclosure relates to a display device and a display system.

### 2. Description of the Related Art

Japanese Patent Application Laid-open Publication No. 2014-232136 (JP-A-2014-232136) and Japanese Patent Application Laid-open Publication No. 2019-113584 (JP-A-2019-113584) disclose display devices that improve response speed and transmittance.

In the technology disclosed in JP-A-2014-232136, increasing the resolution of the pixels makes it difficult to form the comb teeth of the electrodes. In the technology disclosed in JP-A-2019-113584, four liquid crystal domains of the same size are generated around two openings (slits), thereby improving response speed. In the technology disclosed in JP-A-2019-113584, however, increasing the resolution of the pixels may possibly make all the four liquid crystal domains around the two openings (slits) equally small, resulting in reduced transmittance.

An object of the present disclosure is to provide a display device and a display system that improve response speed and transmittance if the resolution of pixels is increased.

### SUMMARY

A display device according to an embodiment includes an array substrate, and a counter substrate facing the array substrate. The array substrate includes a plurality of signal lines arrayed in a first direction in a manner spaced apart from each other, a plurality of scanning lines arrayed in a second direction in a manner spaced apart from each other, a plurality of pixel electrodes provided to respective openings of pixels each surrounded by two adjacent signal lines and two adjacent scanning lines, a plurality of semiconductors provided to the respective pixels, and a common electrode overlapping the pixel electrodes with an insulating film interposed between the common electrode and the pixel electrodes, a slit of the common electrode has a polygonal shape and has a first side and a second side facing the first side and longer than the first side, and the second side overlaps the signal line or the scanning line in plan view.

A display system according to an embodiment includes a lens, the display device above, and a control device configured to output an image to the display device.

### BRIEF DESCRIPTION OF THE DRAWINGS

FIG. 1 is a configuration diagram of an example of a display system according to a first embodiment;

FIG. 2 is a schematic of an example of the relative relation between a display device and the eyes of a user;

FIG. 3 is a block diagram of an example of the configuration of the display system according to the first embodiment;

FIG. 4 is a circuit diagram of a pixel array in a display region according to the first embodiment;

FIG. 5 is a schematic of an example of a display panel according to the first embodiment;

FIG. 6 is an enlarged schematic of part of the display region according to the first embodiment;

FIG. 7 is a sectional view schematically illustrating the section along line VII-VII′ of FIG. 6;

FIG. 8 is a sectional view schematically illustrating the boundary between the display region and a peripheral region according to the first embodiment;

FIG. 9 is a sectional view schematically illustrating the section along line IX-IX′ of FIG. 8;

FIG. 10 is a plan view schematically illustrating the relation between a slit and liquid crystal domains;

FIG. 11 is an enlarged schematic of part of the display region according to a second embodiment;

FIG. 12 is an enlarged schematic of part of the display region according to a third embodiment;

FIG. 13 is an enlarged schematic of part of the display region according to a fourth embodiment; and

FIG. 14 is an enlarged schematic of part of the display region according to a fifth embodiment.

### DETAILED DESCRIPTION

Exemplary aspects (embodiments) to embody the present invention are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the invention and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present specification and the figures, components similar to those previously described with reference to previous figures are denoted by like reference numerals, and detailed explanation thereof may be appropriately omitted.

### First Embodiment

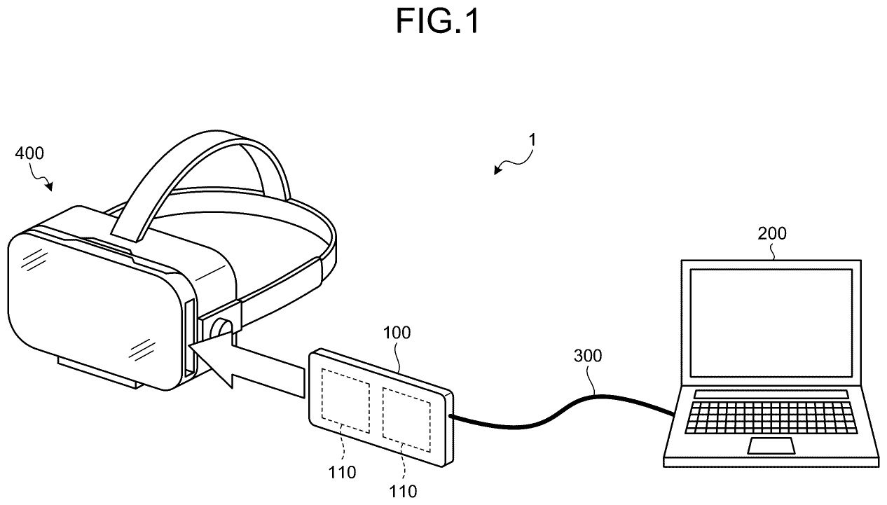

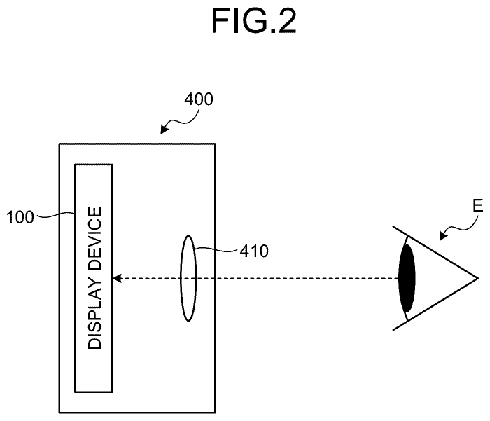

FIG. 1 is a configuration diagram of an example of a display system according to a first embodiment. FIG. 2 is a schematic of an example of the relative relation between a display device and the eyes of a user.

A display system 1 according to the present embodiment is a display system that changes images in synchronization with movement of the user. The display system 1 is, for example, a virtual reality (VR) system that three-dimensionally displays VR images indicating three-dimensional objects or the like in a virtual space and changes the three-dimensional images according to the direction (position) of the user's head, thereby creating a sense of virtual reality for the user.

The display system 1 includes a display device 100 and a control device 200, for example. The display device 100 and the control device 200 can receive and transmit information (signals) via a cable 300. Examples of the cable 300 include, but are not limited to, a universal serial bus (USB) cable, a high-definition multimedia interface (HDMI) (registered trademark) cable, etc. The display device 100 and the control device 200 may be capable of receiving and transmitting information through wireless communications.

The display device 100 is supplied with electric power from the control device 200 via the cable 300. The display device 100, for example, may include a power receiver supplied with electric power from a power supply unit of the control device 200 via the cable 300. In this case, display panels 110, a sensor 120, and other components of the display device 100 may be driven using the electric power supplied from the control device 200. With this configuration, the display device 100 does not require a battery or the like and can be provided as a more reasonable and lighter display device 100. Alternatively, a mounting member 400 or the display device 100 may be provided with a battery to supply electric power to the display device.

The display device 100 includes display panels. The display panel is a liquid crystal display, for example.

The display device 100 is fixed to the mounting member 400. Examples of the mounting member 400 include, but are not limited to, a headset, goggles, a helmet and a mask that cover both eyes of the user, etc. The mounting member 400 is mounted on the user's head. When the mounting member 400 is mounted, it is positioned in front of the user so as to cover both eyes of the user. The mounting member 400 functions as an immersive mounting member by positioning the display device 100 fixed inside in front of both eyes of the user. The mounting member 400 may include an output unit that outputs sound signals or the like output from the control device 200. The mounting member 400 may incorporate the functions of the control device 200.

While the display device 100 in the example illustrated in FIG. 1 is slotted into the mounting member 400, it may be fixed to the mounting member 400. In other words, the display system may be composed of a wearable display device including the mounting member 400 and the display device 100, and the control device 200.

As illustrated in FIG. 2, the mounting member 400 includes a lens 410 corresponding to both eyes of the user, for example. The lens 410 is a magnifying lens to form an image in the eyes of the user. When the mounting member 400 is mounted on the user's head, the lens 410 is positioned in front of the user's eyes E. The user visually recognizes a display region of the display device 100 magnified by the lens 410. Therefore, the display device 100 needs to increase the resolution to clearly display an image (screen). While the configuration according to the present disclosure includes one lens, for example, it may include a plurality of lenses, and the display device 100 may be positioned at a position other than in front of the eyes.

The control device 200, for example, displays images on the display device 100. The control device 200 may be an electronic apparatus, such as a personal computer and a gaming device. Examples of the virtual images include, but are not limited to, computer graphic video images, 360-degree real video images, etc. The control device 200 outputs a three-dimensional image created using the parallax of both eyes of the user to the display device 100. The control device 200 outputs images for the right eye and the left eye that follow the direction of the user's head to the display device 100.

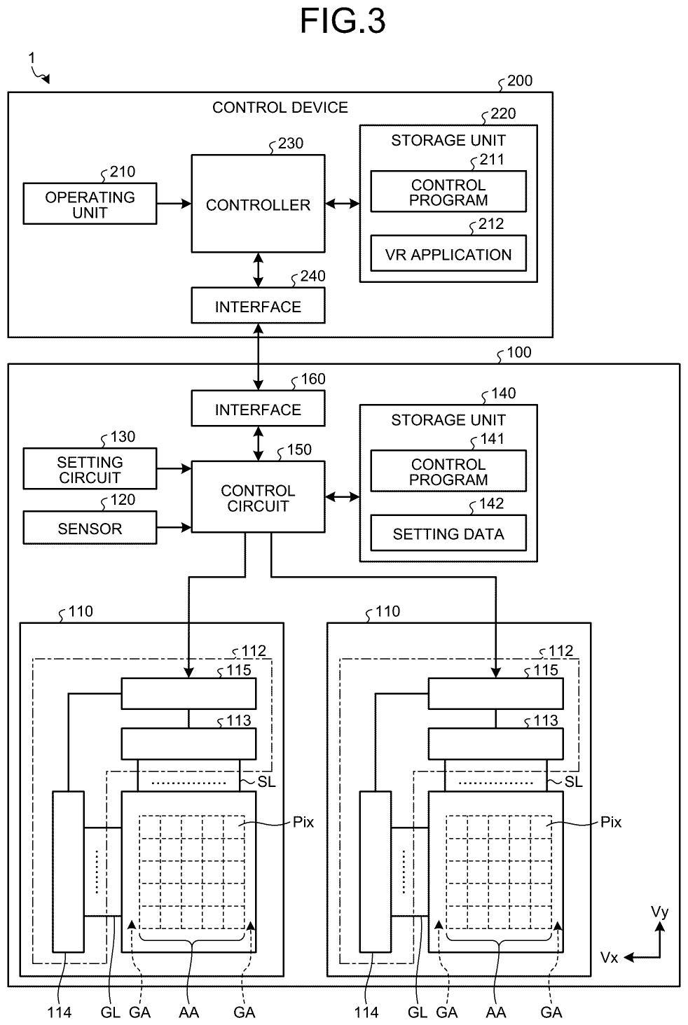

FIG. 3 is a block diagram of an example of the configuration of the display system according to the first embodiment. As illustrated in FIG. 3, the display device 100 includes two display panels 110, a sensor 120, an image separation circuit 150, and an interface 160.

The display device 100 is composed of two display panels 110: one is used as the display panel 110 for the left eye, and the other is used as the display panel 110 for the right eye.

The two display panels 110 each have a display region AA and a display control circuit 112. The display panel 110 includes a light source device, not illustrated, that irradiates the display region AA with light from behind.

In the display region AA, P₀×Q₀ pixels Pix (P₀ pixels Pix in the row direction and Q₀ pixels Pix in the column direction) are arrayed in a two-dimensional matrix (row-column configuration). In the present embodiment, P₀ is 2880, and Q₀ is 1700. FIG. 3 schematically illustrates the array of the pixels Pix, and the array of the pixels Pix will be described later in greater detail. The pixels of the display device are visually recognized through the lens. For this reason, the pixel pitch is 3 μm to 10 μm, for example, and the display region AA is composed of a high-definition array of the pixels Pix. The display region AA is surrounded by the peripheral region GA.

The display panel 110 includes scanning lines extending in an X-direction and signal lines extending in a Y-direction that intersects the X-direction. The display panel 110 includes 2880 signal lines SL and 1700 scanning lines GL, for example. In the display panel 110, the region surrounded by the signal lines SL and the scanning lines GL is provided with the pixel Pix. The pixel Pix includes a switching element SW (thin-film transistor (TFT)) coupled to the signal line SL and the scanning line GL, and a pixel electrode coupled to the switching element SW. One scanning line GL is coupled to a plurality of pixels Pix disposed along the extending direction of the scanning line GL. One signal line SL is coupled to a plurality of pixels Pix disposed along the extending direction of the signal line SL.

The display region AA of one display panel 110 of the two display panels 110 is for the right eye, and the display region AA of the other display panel 110 is for the left eye. The first embodiment describes a case where the display panel 110 includes the two display panels 110 for the left eye and the right eye. The display device 100, however, does not necessarily include two display panels 110 as described above. The display device 100, for example, may include one display panel 110. In this case, the display region of the display panel 110 may be divided into two parts such that the right half region displays images for the right eye and the left half region displays images for the left eye.

The display control circuit 112 includes a driver integrated circuit (IC) 115, a signal line coupling circuit 113, and a scanning line drive circuit 114. The signal line coupling circuit 113 is electrically coupled to the signal lines SL. The driver IC 115 causes the scanning line drive circuit 114 to control ON/OFF of the switching elements (e.g., TFT) for controlling the operation (light transmittance) of the pixels Pix. The scanning line drive circuit 114 is electrically coupled to the scanning lines GL.

The sensor 120 detects information that enables estimation of the direction of the user's head. The sensor 120, for example, detects information indicating the movement of the display device 100 and/or the mounting member 400, and the display system 1 estimates the direction of the head of the user wearing the display device 100 on the head based on the information indicating the movement of the display device 100 and/or the mounting member 400.

The sensor 120 detects the information that enables estimation of the direction of the line of sight using at least one of the angle, acceleration, angular velocity, azimuth, and distance of the display device 100 and/or the mounting member 400, for example. Examples of the sensor 120 include, but are not limited to, a gyro sensor, an acceleration sensor, an azimuth sensor, etc. The sensor 120 may detect the angle and angular velocity of the display device 100 and/or the mounting member 400 by a gyro sensor, for example. The sensor 120 may detect the direction and magnitude of acceleration acting on the display device 100 and/or the mounting member 400 by an acceleration sensor, for example. The sensor 120 may detect the azimuth of the display device 100 by an azimuth sensor, for example. The sensor 120 may detect the movement of the display device 100 and/or the mounting member 400 by a distance sensor or a global positioning system (GPS) receiver, for example. The sensor 120 may be any other sensor, such as an optical sensor, or a combination of a plurality of sensors, as long as it is a sensor that detects the direction of the user's head, changes in the line of sight, movement, or the like. The sensor 120 is electrically coupled to the image separation circuit 150 via the interface 160, which will be described later.

The image separation circuit 150 receives image data for the left eye and image data for the right eye transmitted from the control device 200 via the cable 300. The image separation circuit 150 transmits the image data for the left eye to the display panel 110 that displays images for the left eye and transmits the image data for the right eye to the display panel 110 that displays images for the right eye.

The interface 160 includes a connector to which the cable 300 (FIG. 1) is coupled. The interface 160 receives signals from the control device 200 via the coupled cable 300. The image separation circuit 150 outputs the signals received from the sensor 120 to the control device 200 via the interface 160 and an interface 240. The signals received from the sensor 120 include the information that enables estimation of the direction of the line of sight described above. Alternatively, the signals received from the sensor 120 may be output directly to a controller 230 of the control device 200 via the interface 160. The interface 160 may be a wireless communication device, for example, and transmit and receive information to and from the control device 200 through wireless communications.

The control device 200 includes an operating unit 210, a storage unit 220, the controller 230, and the interface 240.

The operating unit 210 receives operations of the user. The operating unit 210 is an input device, such as a keyboard, buttons, and a touch screen. The operating unit 210 is electrically coupled to the controller 230. The operating unit 210 outputs information corresponding to the operations to the controller 230.

The storage unit 220 stores therein computer programs and data. The storage unit 220 temporarily stores therein the results of processing by the controller 230. The storage unit 220 includes a storage medium. Examples of the storage medium include, but are not limited to, ROM, RAM, a memory card, an optical disc, a magneto-optical disc, etc. The storage unit 220 may store therein data of images to be displayed on the display device 100.

The storage unit 220 stores therein a control program 211 and a VR application 212, for example. The control program 211 can implement functions related to various controls for operating the control device 200, for example. The VR application 212 can implement functions to display virtual reality images on the display device 100. The storage unit 220, for example, can store therein various kinds of information, such as data indicating the detection results of the sensor 120, received from the display device 100.

Examples of the controller 230 include, but are not limited to, a micro control unit (MCU), a central processing unit (CPU), etc. The controller 230 can collectively control the operations of the control device 200. The various functions of the controller 230 are implemented based on the control by the controller 230.

The controller 230 includes a graphics processing unit (GPU) that generates images to be displayed, for example. The GPU generates images to be displayed on the display device 100. The controller 230 outputs the images generated by the GPU to the display device 100 via the interface 240. While the controller 230 of the control device 200 according to the present embodiment includes a GPU, the present embodiment is not limited thereto. For example, the GPU may be provided to the display device 100 or the image separation circuit 150 of the display device 100. In this case, the display device 100 acquires data from the control device 200 or an external electronic apparatus, for example, and the GPU generates the images based on the data.

The interface 240 includes a connector to which the cable 300 (refer to FIG. 1) is coupled. The interface 240 receives signals from the display device 100 via the cable 300. The interface 240 outputs signals received from the controller 230 to the display device 100 via the cable 300. The interface 240 may be a wireless communication device, for example, and may transmit and receive information to and from the display device 100 through wireless communications.

When the controller 230 executes the VR application 212, it displays an image corresponding to the movement of the user (display device 100) on the display device 100. When the controller 230 detects a change in the user (display device 100) while the image is being displayed on the display device 100, it changes the image being displayed on the display device 100 to an image in the direction of the change. When starting to create an image, the controller 230 creates an image based on a reference point of view and a reference line of sight in the virtual space. When the controller 230 detects a change in the user (display device 100), it changes the point of view or the line of sight when creating the image being displayed from the reference point view or the reference line of sight according to the movement of the user (display device 100). The controller 230 displays an image based on the changed point of view or line of sight on the display device 100.

For example, the controller 230 detects the movement of the user's head to the right direction based on the detection results of the sensor 120. In this case, the controller 230 changes the currently displayed image to an image obtained when the line of sight is moved to the right direction. The user can visually recognize the image in the right direction with respect to the image being displayed on the display device 100.

When the controller 230 detects the movement of the display device 100 based on the detection results of the sensor 120, for example, it changes the image according to the detected movement. If the controller 230 detects that the display device 100 has moved forward, it changes the currently displayed image to an image to be displayed when the display device 100 moves forward. If the controller 230 detects that the display device 100 has moved backward, it changes the currently displayed image to an image to be displayed when the display device 100 moves backward. The user can visually recognize the image in the direction of his/her movement from the image being displayed on the display device 100.

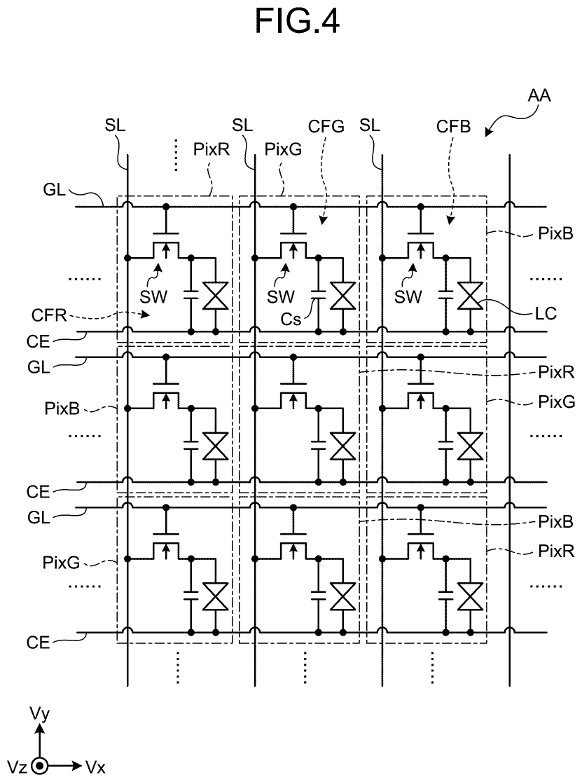

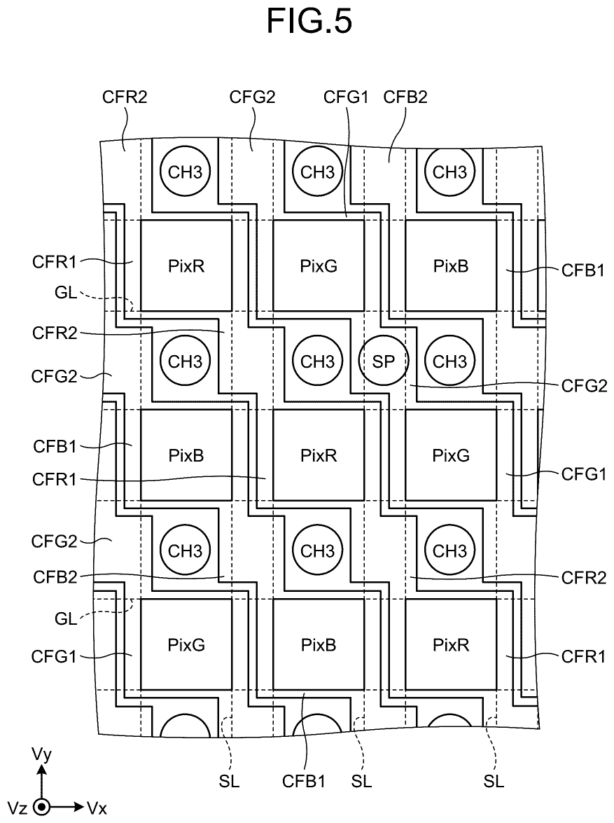

FIG. 4 is a circuit diagram of the pixel array in the display region according to the first embodiment. FIG. 5 is a schematic of an example of the display panel according to the first embodiment. In the present disclosure, the scanning lines GL and the signal lines SL do not necessarily intersect at right angles, but they intersect at right angles in FIG. 4 for the convenience of explanation.

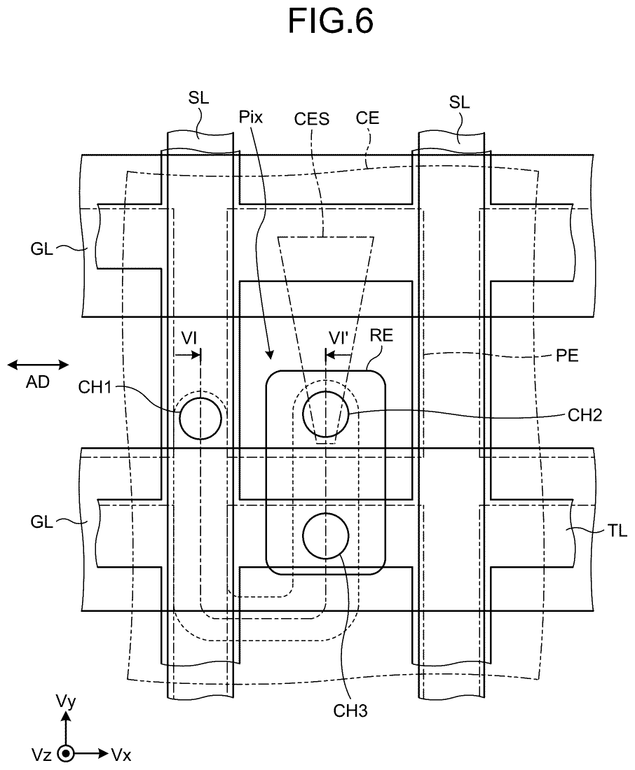

The display region AA is provided with the switching elements SW of pixels PixR, PixG, and PixB, the signal lines SL, the scanning lines GL, and other components as illustrated in FIG. 4. The signal line SL is wiring for supplying pixel signals to pixel electrodes PE (refer to FIG. 6). The scanning line GL is wiring for supplying gate signals that drive the switching elements SW.

As illustrated in FIG. 4, the pixels PixR, PixG, and PixB each include the switching element SW and capacitance of a liquid crystal layer LC. The switching element SW is composed of a thin-film transistor and is composed of an re-channel metal oxide semiconductor (MOS) TFT in this example. An insulating film is provided between the pixel electrode PE and a common electrode CE, which will be described later, and holding capacitance Cs illustrated in FIG. 4 is formed between the pixel electrode PE and the common electrode CE.

In color filters CFR1, CFG1, and CFB1 illustrated in FIG. 5, color regions colored in three colors of red (first color: R), green (second color: G), and blue (third color: B), for example, are periodically arrayed. The three color regions, R, G, and B correspond to the pixels PixR, PixG, and PixB, respectively, illustrated in FIG. 4. A set of the pixels PixR, PixG, and PixB corresponding to the three color regions serves as a pixel. The color filter may include four or more color regions. The pixels PixR, PixG, and PixB may be referred to as sub-pixels.

The color filters CFR1, CFG1, and CFB1 illustrated in FIG. 5 are disposed in openings surrounded by two signal lines SL and two scanning lines GL.

As illustrated in FIGS. 4 and 5, the pixel PixR is sandwiched between the pixel PixB and the pixel PixG in a direction Vx (first direction) and between the pixel PixB and the pixel PixG in a direction Vy (second direction).

The pixel PixG is sandwiched between the pixel PixR and the pixel PixB in the direction Vx and between the pixel PixR and the pixel PixB in the direction Vy.

The pixel PixB is sandwiched between the pixel PixG and the pixel PixR in the direction Vx and between the pixel PixG and the pixel PixR in the direction Vy.

The pixel PixR, the pixel PixG, and the pixel PixB are repeatedly arrayed in order in the direction Vx. The pixel PixR, the pixel PixB, and the pixel PixG are repeatedly arrayed in order in the direction Vy. In the arrangement in the direction Vy, the pixel PixR, the pixel PixG, and the pixel PixB may be repeatedly arrayed in order.

The color filters CFR1 are coupled by a color filter CFR2 in the same red color. By coupling the color filters CFR1 and the color filters CFR2, the color filters in the same color are disposed in an oblique direction intersecting the direction Vx and the direction Vy. Similarly, the color filters CFG1 are coupled by a color filter CFG2 in the same green color, and the color filters CFB1 are coupled by a color filter CFB2 in the same blue color.

The color filter CFR1 and the color filter CFR2 are integrally formed. For the convenience of explanation, the color filter CFR1 and the color filter CFR2 are hereinafter referred to as a color filter CFR when they are not distinguished from each other. Similarly, the color filter CFG1 and the color filter CFG2 are hereinafter referred to as a color filter CFG when they are not distinguished from each other. The color filter CFB1 and the color filter CFB2 are hereinafter referred to as a color filter CFB when they are not distinguished from each other. Furthermore, the color filter CFR, the color filter CFG, and the color filter CFB are referred to as a color filter CF when they are not distinguished from one another.

A spacer SP illustrated in FIG. 5 is a member that regulates the distance between an array substrate SUB1 and a counter substrate SUB2. The material of the spacer SP is acrylic resin, for example. The spacer SP has a cylindrical shape, and the maximum diameter of the spacer SP is illustrated in FIG. 5. The spacer SP does not necessarily have a cylindrical shape and may be formed as a prismatic spacer, for example. While one spacer is illustrated as an example in FIG. 5, a plurality of spacers are disposed in the actual configuration.

FIG. 6 is an enlarged schematic of part of the display region according to the first embodiment. The pixel Pix illustrated in FIG. 6 is any one of the pixel PixR, the pixel PixG, and the pixel PixB. In the following description, the pixel PixR, the pixel PixG, and the pixel PixB are referred to as the pixels Pix when they are not distinguished from one another.

The signal lines SL are arrayed in the direction Vx in a manner spaced apart from each other. The scanning lines GL are arrayed in the direction Vy in a manner spaced apart from each other. A conductive layer TL overlaps the signal lines SL and the scanning lines GL and has a grid shape in plan view. The width of the conductive layer TL in the direction Vx is larger than that of the signal line SL in the direction Vx. The width of the scanning line GL in the direction Vy is larger than that of the conductive layer TL in the direction Vy.

In each pixel Pix, the pixel electrode PE and the switching element SW are disposed in the opening surrounded by two signal lines SL and two scanning lines GL. The common electrode CE is a common electrode provided across a plurality of pixels Pix. The common electrode CE has a slit CES at each opening surrounded by two signal lines SL and two scanning lines GL.

The slit CES is a part of the common electrode CE without translucent conductive material. The slit CES overlaps the pixel electrode PE. The slit CES has a quadrilateral shape, and specifically has a trapezoidal shape with a pair of opposite sides having different lengths.

As illustrated in FIG. 6, a semiconductor SC is formed in a U-shape. The signal line SL and the semiconductor SC are electrically coupled through a contact hole CH1. The semiconductor SC and a relay electrode RE are electrically coupled through a contact hole CH2. The relay electrode RE and the pixel electrode PE are electrically coupled through a contact hole CH3.

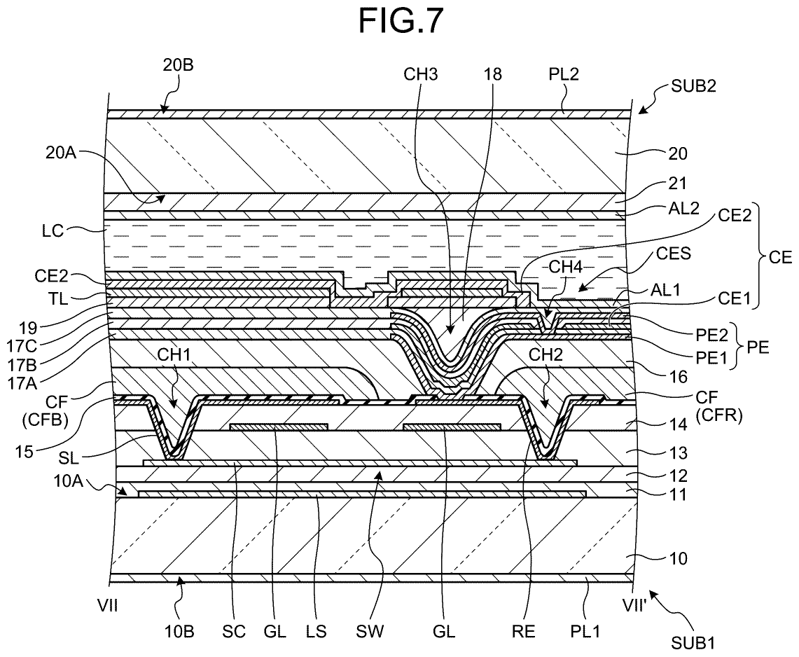

FIG. 7 is a sectional view schematically illustrating the section along line VII-VII′ of FIG. 6. As illustrated in FIG. 5, the color filter CF according to the first embodiment is provided to the array substrate SUB1. The display device 100 has what is called a color filter on array (COA) structure in which the color filters CF, the pixel electrodes PE, and the common electrode CE are disposed on the array substrate SUB1.

As illustrated in FIG. 7, the array substrate SUB1 is formed using a first insulating substrate 10 with translucency, such as a glass or resin substrate, as a base. The array substrate SUB1 includes a light-shielding layer LS, a first insulating film 11, a second insulating film 12, a third insulating film 13, a fourth insulating film 14, the color filter CF, a fifth insulating film 15, a pixel electrode PE1, a sixth insulating film 16, a common electrode CE1, a seventh insulating film 17, a pixel electrode PE2, a first planarization film 18, a second planarization film 19, the conductive layer TL, a common electrode CE2, a first orientation film AL1, and other components on the surface of the first insulating substrate facing the counter substrate SUB2. In the following description, the direction from the array substrate SUB1 toward the counter substrate SUB2 is referred to as an upper side or simply as up.

The light-shielding layer LS is positioned on the first insulating substrate 10. The first insulating film 11 is positioned on the light-shielding layer LS and an inner surface 10A of the first insulating substrate 10. The second insulating film 12 is positioned on the first insulating film 11. The semiconductor SC is positioned on the second insulating film 12. The third insulating film 13 is positioned on the semiconductor SC and the second insulating film 12. The gate electrode of the scanning line GL is positioned on the third insulating film 13.

The fourth insulating film 14 is positioned on the gate electrode of the scanning line GL and the third insulating film 13. A hole is formed at a position overlapping the semiconductor SC in the third insulating film 13 and the fourth insulating film 14 to form the contact hole CH1. The signal line SL formed on the fourth insulating film 14 is electrically coupled to the semiconductor SC through the contact holes CH1.

A hole is formed at a position overlapping the semiconductor SC in the third insulating film 13 and the fourth insulating film 14 to form the contact hole CH2. The relay electrode RE formed on the fourth insulating film 14 is electrically coupled to the semiconductor SC through the contact holes CH2.

The fifth insulating film 15 is positioned on the signal line SL, the relay electrode RE, and the fourth insulating film 14. The color filter CF is positioned on the fifth insulating film 15. The sixth insulating film 16 is positioned on the color filter CF and the fifth insulating film 15.

A hole is formed at a position overlapping the relay electrode RE in the fifth insulating film 15 and the sixth insulating film 16 to form the contact hole CH3. The pixel electrode PE1 is electrically coupled to the relay electrode RE through the contact hole CH3. A first intermediate insulating film 17A is positioned on the sixth insulating film 16 and the pixel electrode PE1. The pixel electrode PE1 is made of translucent conductive material, such as indium tin oxide (ITO), indium zinc oxide (IZO), and indium gallium oxide (IGO).

The common electrode CE1 is positioned on the first intermediate insulating film 17A. The common electrode CE1 is made of translucent conductive material, such as ITO, IZO, and IGO. A second intermediate insulating film 17B is positioned on the common electrode CE1 and the first intermediate insulating film 17A. The pixel electrode PE2 is positioned on the second intermediate insulating film 17B. The pixel electrode PE2 is made of translucent conductive material, such as ITO, IZO, and IGO. A contact hole CH4 is formed in the second intermediate insulating film 17B. While the second intermediate insulating film 17B electrically insulates the pixel electrode PE2 from the common electrode CE1, the pixel electrode PE2 is electrically coupled to the pixel electrode PE1 through the contact hole CH4.

A third intermediate insulating film 17C is positioned on the pixel electrode PE2 and the second intermediate insulating film 17B. The first intermediate insulating film 17A, the second intermediate insulating film 17B, and the third intermediate insulating film 17C constitute the seventh insulating film.

In the contact hole CH3, a recess of the surface of the third intermediate insulating film 17C is formed, and the recess is planarized by the first planarization film 18. The second planarization film 19 is positioned on the third intermediate insulating film 17C and the first planarization film 18.

The first planarization film 18 is made of novolac resin or acrylic resin. The second planarization film 19 may be made of the same material as or different material from that of the first planarization film 18. The second planarization film 19 is an inorganic insulating film made of silicon nitride or an organic insulating film made of novolac resin or acrylic resin, for example.

The conductive layer TL is positioned on the second planarization film 19. The conductive layer TL is a conductor and is electrically coupled to the common electrode CE. Therefore, the resistance per unit area of the common electrode CE and the conductive layer TL is small. The conductive layer TL may be a single layer of metal, such as aluminum (Al). Alternatively, the conductive later TL may be composed of a plurality of metal layers, such as titanium/aluminum/titanium and molybdenum/aluminum/molybdenum, by disposing titanium (Ti) and molybdenum (Mo) on and under aluminum.

The common electrode CE2 is positioned on the conductive layer TL and the second planarization film 19. The common electrode CE2 and the slit CES are covered by the first orientation film AL1.

The counter substrate SUB2 is formed using a second insulating substrate 20 with translucency, such as a glass or resin substrate, as a base. The counter substrate SUB2 includes an overcoat layer 21 and a second orientation film AL2 on the surface of the second insulating substrate 20 facing the array substrate SUB1.

The array substrate SUB1 and the counter substrate SUB2 are disposed with the first orientation film AL1 and the second orientation film AL2 facing each other. The liquid crystal layer LC is interposed between the first orientation film AL1 and the second orientation film AL2. The long axis of the liquid crystal molecules is oriented orthogonal or parallel to an initial orientation direction AD illustrated in FIG. 6 by the first orientation film AL1 and the second orientation film AL2. The liquid crystal layer LC is made of negative liquid crystal material with negative dielectric anisotropy or positive liquid crystal material with positive dielectric anisotropy. The orientation of the liquid crystal layer LC is stable when voltage is applied to the liquid crystal layer LC, and a fast response of the liquid crystal molecules can be maintained. If the liquid crystal layer LC is made of negative liquid crystal material, the long axis of the liquid crystal molecules extends along a direction parallel to the initial orientation direction AD illustrated in FIG. 6. If the liquid crystal layer LC is made of positive liquid crystal material, the long axis of the liquid crystal molecules extends along a direction orthogonal to the initial orientation direction AD illustrated in FIG. 6.

The array substrate SUB1 faces a backlight unit, and the counter substrate SUB2 is positioned on the display surface side. While various kinds of backlight units are applicable, detailed description of their structure is omitted.

A first optical element OD1 including a first polarizing plate PL1 is disposed on an outer surface 10B of the first insulating substrate 10 or the surface facing the backlight unit. A second optical element OD2 including a second polarizing plate PL2 is disposed on an outer surface 20B of the second insulating substrate 20 or the surface on the observation position side. The first polarization axis of the first polarizing plate PL1 and the second polarization axis of the second polarizing plate PL2 are in a crossed-Nicoles positional relation in the Vx-Vy plane, for example. The first optical element OD1 and the second optical element OD2 may include other optical functional elements, such as a retardation plate.

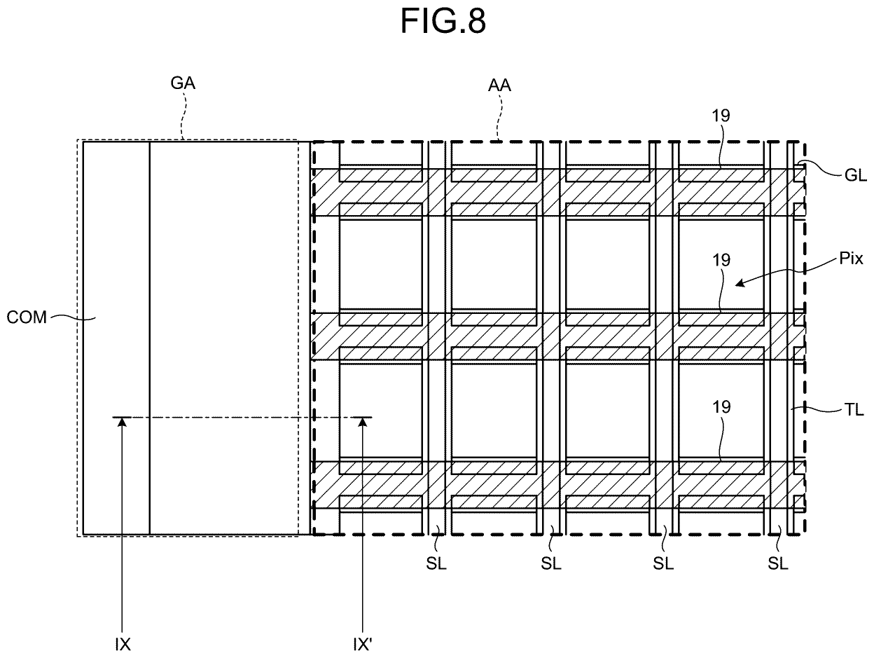

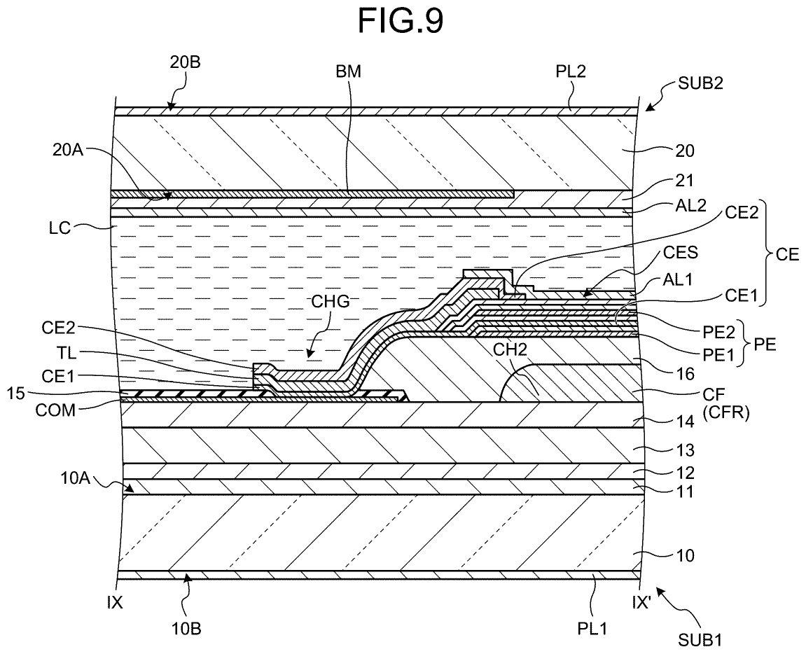

FIG. 8 is a sectional view schematically illustrating the boundary between the display region and the peripheral region according to the first embodiment. FIG. 9 is a sectional view schematically illustrating the section along line IX-IX′ of FIG. 8.

As illustrated in FIGS. 8 and 9, wiring COM for supplying a common potential is disposed on the fourth insulating film 14 in the peripheral region GA. The fifth insulating film 15 covers and protects the wiring COM. A contact hole CHG is formed in part of the fifth insulating film 15, and the wiring COM is electrically coupled to the common electrode CE1, the conductive layer TL, and the common electrode CE2 drawn from the display region AA through the contact hole CHG.

As illustrated in FIG. 8, the second planarization film 19 is formed along the scanning line GL and has a strip shape. The area of the second planarization film 19 is equal to or smaller than that of the scanning line GL. More preferably, the area of the second planarization film 19 is smaller than that of the scanning line GL in consideration of misalignment. As a result, the second planarization film 19 is formed inside the scanning line GL. The second planarization film 19 is not present inside the opening surrounded by the two adjacent conductive layers TL formed along the signal lines SL and the two adjacent scanning lines GL. As a result, the slit CES in the opening is not covered by the second planarization film 19, and the second planarization film 19 does not suppress the electric field from the pixel electrode PE.

As illustrated in FIGS. 8 and 9, a light-shielding layer BM is provided to the counter substrate SUB2 in the peripheral region GA and can conceal the peripheral region GA of the array substrate SUB1. As illustrated in FIGS. 7 and 9, the light-shielding layer BM is not provided to the counter substrate SUB2 in the display region AA. The light-shielding layer BM is made of black resin material.

The second planarization film 19 may be formed along the conductive layer TL and have a grid shape. The area of the second planarization film 19 is equal to or smaller than that of the conductive layer TL. More preferably, the area of the second planarization film 19 is smaller than that of the conductive layer TL in consideration of misalignment. As a result, the second planarization film 19 is formed inside the scanning line GL. The second planarization film 19 is not present inside the opening surrounded by the two adjacent conductive layers TL formed along the signal lines SL and the two adjacent scanning lines GL. As a result, the slit CES in the opening is not covered by the second planarization film 19, and the second planarization film 19 does not suppress the electric field from the pixel electrode PE.

Let us assume a comparative example where the counter substrate SUB2 is provided with the color filter and the light-shielding layer positioned at the boundary between the colors of the color filter unlike the first embodiment. In the comparative example, the position of the opening of the pixel Pix on the array substrate may be more likely to overlap the position of the light-shielding layer in the display region AA of the counter substrate SUB2 as the pixel Pix is smaller. By contrast, in the COA structure according to the first embodiment illustrated in FIGS. 8 and 9, the display region AA of the counter substrate SUB2 is not provided with the color filter CF or the light-shielding layer positioned at the boundary between the colors of the color filter CF. Therefore, light passing through the opening of the pixel Pix is not blocked if the pixel Pix is small.

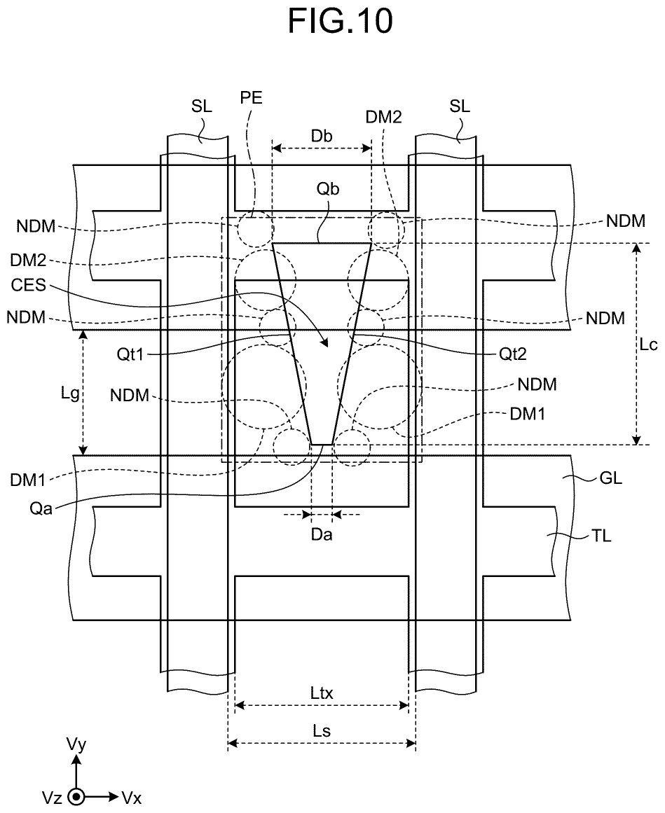

FIG. 10 is a plan view schematically illustrating the relation between the slit and liquid crystal domains. As illustrated in FIG. 10, the slit CES has an isosceles trapezoidal shape. The slit CES has a first side Qa, a second side Qb, a third side Qt1, and a fourth side Qt2. The first side Qa and the second side Qb face each other and are parallel. The third side Qt1 and the fourth side Qt2 face each other and are not parallel. The distance between the third side Qt1 and the fourth side Qt2 decreases as closer to the first side Qa.

The distance Db of the second side Qb is larger than the distance Da of the first side Qa. The distance of the third side Qt1 is equal to that of the fourth side Qt2. The distance Db of the second side Qb is approximately 2 μm to 3 μm. The distance Da of the first side Qa is smaller than 2 μm. If the distance Da of the first side Qa is substantially zero, and the third side Qt1 and the fourth side Qt2 intersect, the slit CES has a triangular shape. The slit CES simply needs to have a polygonal shape with three or more vertices and may have a pentagonal, hexagonal, or octagonal shape.

The distance Lc from the first side Qa to the second side Qb is larger than the opening distance Lg between the scanning lines GL in the direction Vy. The distance Db of the second side Qb is smaller than the distance Ltx of the opening between the conductive layers TL in the direction Vx. The distance Ltx is larger than the distance Ls of the opening between the signal lines SL in the direction Vx.

The display device according to the first embodiment has dark regions NDM at the positions on the electrode positioned at the center of the third side Qt1 of the slit CES, the center of the fourth side Qt2 of the slit CES, and the corners of the slit CES. In the dark regions NDM, the orientation of the liquid crystal molecules hardly changes.

If the liquid crystal layer LC is made of negative liquid crystal material, and no voltage is applied to the liquid crystal layer LC, for example, the liquid crystal molecules LM are initially oriented with their long axis extending toward the inside of the slit CES at the corners of the slit CES. The liquid crystal molecules in the regions near the third side Qt1 and the fourth side Qt2 disposed adjacently are inclined in opposite directions with respect to the direction Vy. By contrast, when voltage is applied to the liquid crystal layer LC, that is, in an ON state where an electric field is formed between the pixel electrode PE and the common electrode CE, the liquid crystal molecules LM are affected by the electric field, and their orientation state changes. As illustrated in FIG. 10, liquid crystal domains DM1 and DM2 are formed between the dark regions NDM. In the liquid crystal domains DM1 and DM2, when voltage is applied between the pixel electrode PE and the common electrode CE, the liquid crystal molecules near the third side Qt1 and the fourth side Qt2 facing each other in the same slit CES rotate in opposite directions. When voltage is applied between the pixel electrode PE and the common electrode CE, the polarization state of incident linearly polarized light changes depending on the orientation state of the liquid crystal molecules LM as the linearly polarized light passes through the liquid crystal layer LC.

The liquid crystal domains DM1 and DM2 are sandwiched between the dark regions NDM with a short pitch. Therefore, the liquid crystal molecules in the liquid crystal domains DM1 and DM2 respond faster than those in a lateral electric field liquid crystal display device, such as a fringe field switching (FFS) or in-plane switching (IPS) liquid crystal display device.

The liquid crystal domain DM1 is larger than the liquid crystal domain DM2 because the distance Db of the second side Qb is longer than the distance Da of the first side Qa. The second side Qb overlaps the scanning line GL and the conductive layer TL. The end of the scanning line GL intersects the third side Qt1 and the fourth side Qt2. As a result, the dark regions NDM near the corners on the second side Qb are made inconspicuous.

The conductive layer TL overlaps the liquid crystal domain DM2. As the resolution of the pixels Pix increases, the liquid crystal domain DM2 becomes smaller, and the transmittance of the liquid crystal domain DM2 decreases. With the conductive layer TL overlapping the liquid crystal domain DM2, changes in transmittance of the liquid crystal domain DM2 are less likely to be recognized as noise by a viewer.

In the display device according to the first embodiment, the liquid crystal domain DM1 is larger than the liquid crystal domain DM2. If the pixel Pix becomes smaller for higher resolution, all the four liquid crystal domains around the slit CES do not become equally small. The ratio of the area of the liquid crystal domain DM1 to the area of the opening of the pixel Pix is larger, thereby relatively improving the transmittance.

The display region AA of the counter substrate SUB2 is provided with no light-shielding layer. This configuration reduces the effect of overlapping misalignment between the array substrate SUB1 and the counter substrate SUB2.

### Second Embodiment

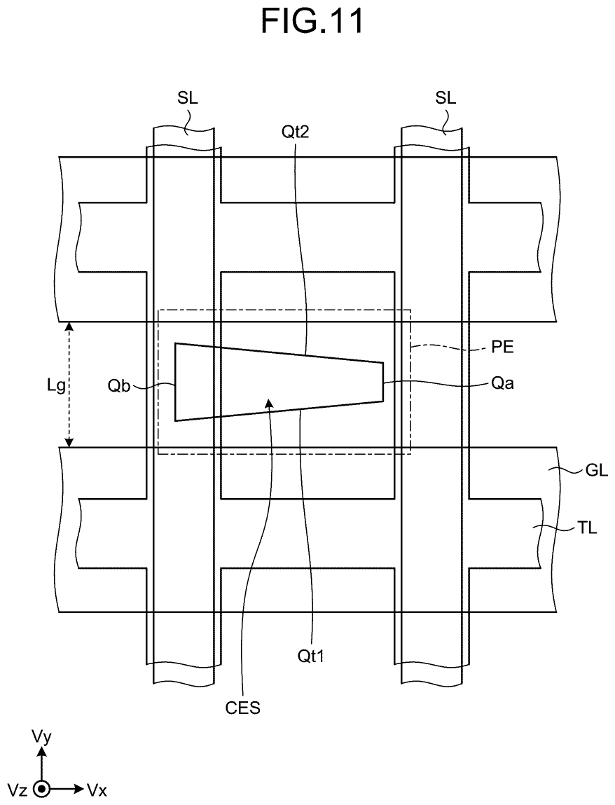

FIG. 11 is an enlarged schematic of part of the display region according to a second embodiment. In the following description, like components may be denoted by like reference numerals. In addition, duplicate explanation thereof is omitted. The second embodiment is different from the first embodiment in that the second side Qb overlaps the signal line SL in plan view.

As illustrated in FIG. 11, the end of the signal line SL with which the second side Qb overlaps intersects the third side Qt1 and the fourth side Qt2. As a result, the dark regions NDM near the corners on the second side Qb are made inconspicuous. The distance of the second side Qb is smaller than the opening distance Lg between the scanning lines GL in the direction Vy.

The second side Qb overlaps the signal line SL and the conductive layer TL. The signal line SL and the conductive layer TL overlap the liquid crystal domain DM2. As the resolution of the pixels Pix increases, the liquid crystal domain DM2 becomes smaller, and the transmittance of the liquid crystal domain DM2 decreases. With the signal line SL and the conductive layer TL overlapping the liquid crystal domain DM2, changes in transmittance of the liquid crystal domain DM2 are less likely to be recognized as noise by the viewer.

### Third Embodiment

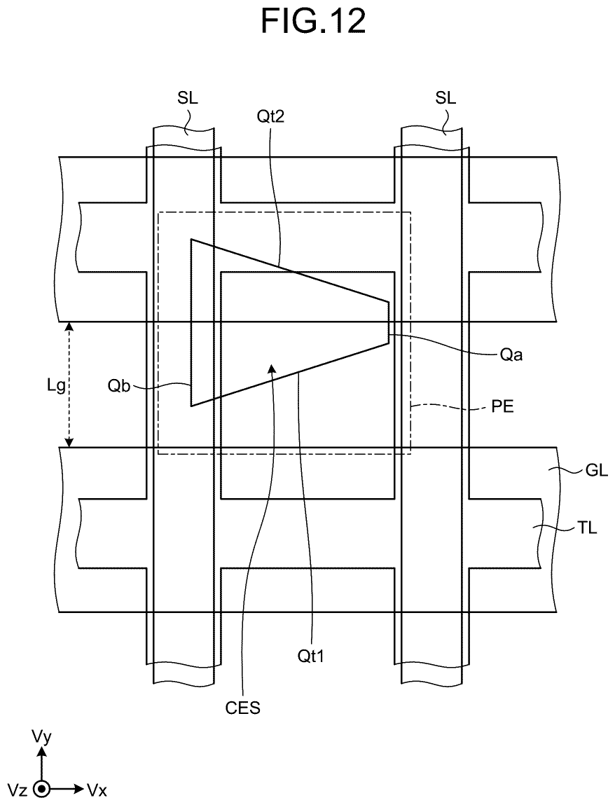

FIG. 12 is an enlarged schematic of part of the display region according to a third embodiment. In the following description, components similar to those according to the first and the second embodiments are denoted by like reference numerals, and duplicate explanation thereof is omitted. The third embodiment is different from the second embodiment in that the fourth side Qt2 overlaps the scanning line GL and the conductive layer TL in plan view.

As illustrated in FIG. 12, the end of the signal line SL with which the second side Qb overlaps intersects the third side Qt1 and the fourth side Qt2. The end of the conductive layer TL intersects the first side Qa and the second side Qb. As a result, the dark regions NDM near the corners on the second side Qb and near the fourth side Qt2 are made inconspicuous. The distance of the second side Qb is smaller than the opening distance Lg between the scanning lines GL in the direction Vy.

The ratio of the area of the liquid crystal domain near the third side Qt1 to the area of the opening increases, thereby relatively improving the transmittance.

### Fourth Embodiment

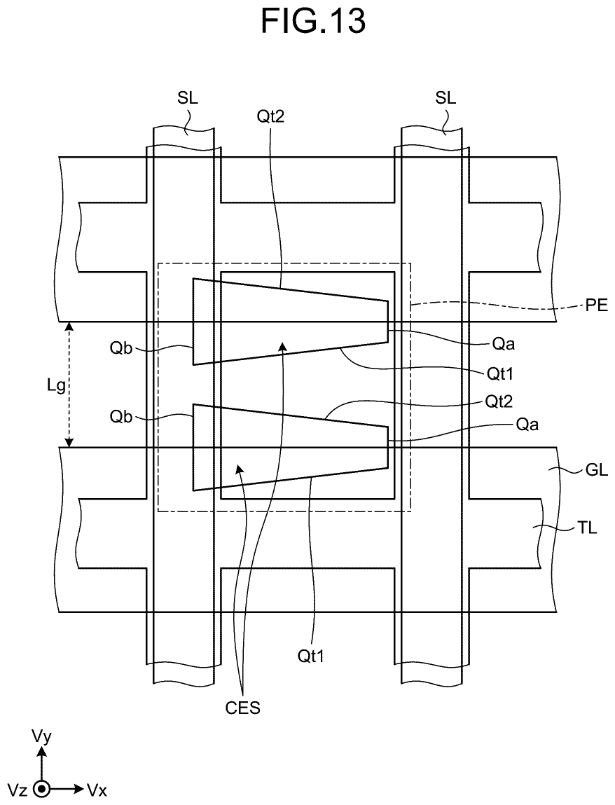

FIG. 13 is an enlarged schematic of part of the display region according to a fourth embodiment. In the following description, components similar to those according to the first to the third embodiments are denoted by like reference numerals, and duplicate explanation thereof is omitted.

The fourth embodiment is different from the second embodiment in that a plurality of slits CES are formed in the pixel. The adjacent slits CES are line-symmetric about the axis of symmetry in the direction Vx between the adjacent slits CES.

With this configuration, the direction of rotation of the liquid crystal molecules near the third side Qt1 of one slit CES is opposite to the direction of rotation of the liquid crystal molecules near the fourth side Qt2 of the other slit CES. As a result, the response speed of rotation of the liquid crystal molecules is improved.

### Fifth Embodiment

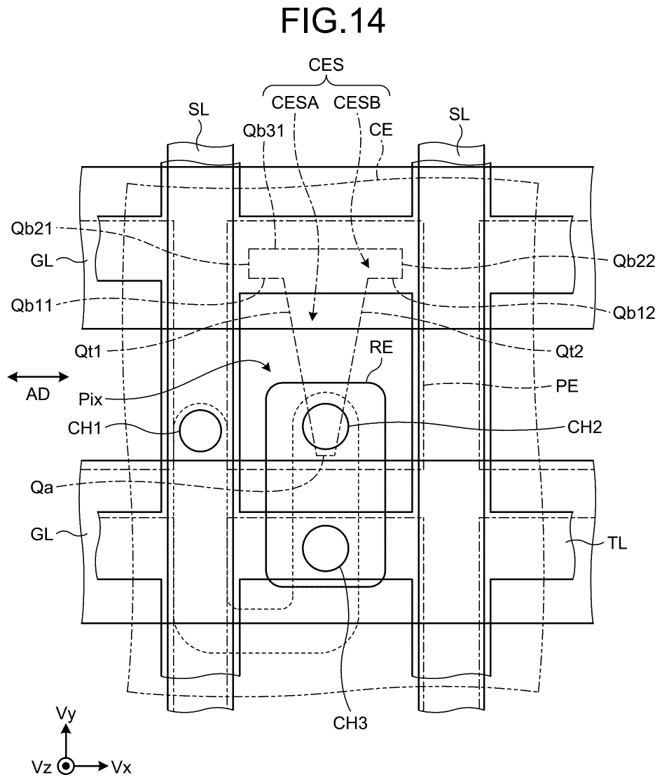

FIG. 14 is an enlarged schematic of part of the display region according to a fifth embodiment. In the following description, components similar to those according to the first to the fourth embodiments are denoted by like reference numerals, and duplicate explanation thereof is omitted.

The fifth embodiment is different from the first embodiment in that the slit CES has a polygonal shape including a trapezoid.

Specifically, as illustrated in FIG. 14, the slit CES has a polygonal shape with a trapezoidal region CESA and a rectangular region CESB. The trapezoidal region CESA has the first side Qa, the third side Qt1, and the fourth side Qt2. The side corresponding to the second side Qb according to the first embodiment is a virtual line connecting a side Qb11 and a side Qb12 of the rectangular region CESB or a side Qb31. The rectangular region CESB overlaps the scanning line GL. The virtual line connecting the side Qb11 and the side Qb12 or the side Qb31 also overlaps the scanning line GL. The rectangular region CESB has the side Qb11, the side Qb12, a side Qb21, a side Qb22, and the side Qb31. The first side Qa and the side Qb31 face each other and are parallel. The third side Qt1 and the fourth side Qt2 face each other and are not parallel. The distance between the third side Qt1 and the fourth side Qt2 decreases as closer to the first side Qa.

In the slit CES according to the fifth embodiment, the dark region formed at the intersection of the side Qb11 and the third side Qt1 and the dark region formed at the intersection of the side Qb12 and the fourth side Qt2 are stable. Therefore, the state of the liquid crystal domain is stable. The slit CES according to the fifth embodiment may have the same structure as that according to the second to the fourth embodiments. In this case, the rectangular region CESB overlaps the signal line SL.

While the exemplary embodiments have been described, the embodiments are not intended to limit the present disclosure. The contents disclosed in the embodiments are given by way of example only, and various modifications may be made without departing from the spirit of the present disclosure. Appropriate modifications made without departing from the spirit of the present disclosure naturally fall within the technical scope of the present disclosure.

What is claimed is:

1. A display device comprising:
an array substrate; and
a counter substrate facing the array substrate, wherein
the array substrate comprises:
a plurality of signal lines arrayed in a first direction in a manner spaced apart from each other;
a plurality of scanning lines arrayed in a second direction in a manner spaced apart from each other;
a plurality of pixel electrodes provided to respective openings of pixels each surrounded by two adjacent signal lines and two adjacent scanning lines;
a plurality of semiconductors provided to the respective pixels; and
a common electrode overlapping the pixel electrodes with an insulating film interposed between the common electrode and the pixel electrodes,
a slit of the common electrode has a polygonal shape and has a first side and a second side facing the first side and longer than the first side, and
the second side overlaps the signal line or the scanning line in plan view.

2. The display device according to claim 1, wherein the slit of the common electrode has a third side and a fourth side connecting the first side and the second side, and an end of the scanning line with which the second side overlaps intersects the third side and the fourth side in plan view.

3. The display device according to claim 2, comprising a conductive layer overlapping the signal lines and the scanning lines and having a grid shape in plan view, wherein the second side overlaps the conductive layer in plan view.

4. The display device according to claim 1, wherein the slit of the common electrode has a third side and a fourth side connecting the first side and the second side, and an end of the signal line with which the second side overlaps intersects the third side and the fourth side in plan view.

5. The display device according to claim 4, comprising a conductive layer overlapping the signal lines and the scanning lines and having a grid shape in plan view, wherein the second side overlaps the conductive layer in plan view.

6. The display device according to claim 1, wherein the slit of the common electrode includes a trapezoid.

7. A display system comprising:
a lens;
a display device according to claim 1; and
a control device configured to output an image to the display device.
